(19) United States
(12) Patent Application Publication
(10) Pub. No.: US 2025/0112030 A1
(43) Pub. Date: Apr. 3, 2025

(54) PLASMA PROCESSING APPARATUS

(71) Applicants: Beijing E-Town Semiconductor Technology Co., Ltd., Beijing (CN); Mattson Technology, Inc., Fremont, CA (US)

(72) Inventors: Kenneth Scott Alexander Butcher, Thunder Bay (CA); Vasil Milchev Georgiev, Thunder Bay (CA)

(21) Appl. No.: 18/891,766

(22) Filed: Sep. 20, 2024

Related U.S. Application Data
(60) Provisional application No. 63/586,230, filed on Sep. 28, 2023.

(51) Int. Cl. H01J 37/32

(52) U.S. Cl. CPC H01J 37/32651; H01J 37/3244; H01J 37/32596; H01J 37/32697; H01J 37/32715; H01J 2237/3346

(57) ABSTRACT

Disclosed is a plasma processing apparatus including a processing chamber and a workpiece support disposed in the processing chamber configured to support a workpiece during processing. The apparatus includes a hollow cathode disposed in the processing chamber that is configured to produce a plasma in the processing chamber. The hollow cathode is disposed adjacent to a perimeter of the workpiece support and the workpiece. The apparatus includes a gas distribution system configured to provide process gas to the processing chamber. Methods for processing workpieces are also disclosed.

### PRIORITY CLAIM

The present application is based on and claims priority to U.S. Provisional Application 63/586,230 having a filing date of Sep. 28, 2023, which is incorporated by reference herein.

### FIELD

The present disclosure relates generally to a plasma processing apparatus for plasma processing of a workpiece. More specifically, the present disclosure is directed to a plasma processing system including a hollow cathode.

### BACKGROUND

RF plasmas are used in the manufacture of devices such as integrated circuits, micromechanical devices, flat panel displays, and other devices. RF plasma sources used in modern plasma etch applications are required to provide a high plasma uniformity and a plurality of plasma controls, including independent plasma profile, plasma density, and ion energy controls. RF plasma sources typically must be able to sustain a stable plasma in a variety of process gases and under a variety of different conditions (e.g., gas flow, gas pressure, etc.). In addition, it is desirable that RF plasma sources produce a minimum impact on the environment by operating with reduced energy demands and reduced EM emission.

Problems with plasma processing can include processing uniformity and difficulty processing only certain portions of a workpiece while not processing or damaging other portions of the workpiece. For instance, for certain applications it may be desirable to etch or remove materials from certain areas of the workpiece (e.g., the perimeter) while not damaging or removing any other materials from other areas of the workpiece. Accordingly, improved plasma processing apparatuses and systems are needed.

### SUMMARY

Aspects and advantages of embodiments of the present disclosure will be set forth in part in the following description, or may be learned from the description, or may be learned through practice of the embodiments.

Aspects of the present disclosure are directed to a plasma processing apparatus including a processing chamber having a workpiece support disposed therein that is configured to support a workpiece during processing. A hollow cathode is disposed in the processing chamber and is configured to produce a plasma in the processing chamber. The hollow cathode is disposed adjacent to a perimeter of the workpiece support and the workpiece. The apparatus further includes a gas distribution system configured to provide process gas to the processing chamber.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a cross-sectional schematic view of an example plasma processing apparatus according to example embodiments of the present disclosure.

FIG. 2 depicts a cross-sectional schematic view of an example plasma processing apparatus according to example embodiments of the present disclosure.

FIG. 3 depicts an example top down view of a gas showerhead for a plasma processing apparatus according to example embodiments of the present disclosure.

FIG. 4 depicts a perspective view of an example hollow cathode for a plasma processing apparatus according to example embodiments of the present disclosure.

FIG. 5 depicts a cross-sectional schematic view of an example hollow cathode for a plasma processing apparatus according to example embodiments of the present disclosure.

FIG. 6 depicts a perspective view of an example shield for a plasma processing apparatus according to example embodiments of the present disclosure.

FIG. 7 depicts a cross-sectional schematic view of a portion of an example plasma processing apparatus according to example embodiments of the present disclosure.

FIG. 8 depicts a cross-sectional schematic view of a portion of an example plasma processing apparatus according to example embodiments of the present disclosure.

FIG. 9 depicts a flow chart diagram of a method for processing a workpiece according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Aspects of the present disclosure are discussed with reference to a “workpiece” “wafer” or semiconductor wafer for purposes of illustration and discussion. Those of ordinary skill in the art, using the disclosures provided herein, will understand that the example aspects of the present disclosure can be used in association with any semiconductor workpiece or other suitable workpiece. In addition, the use of the term “about” in conjunction with a numerical value is intended to refer to within ten percent (10%) of the stated numerical value. A “pedestal” refers to any structure that can be used to support a workpiece. A “remote plasma” refers to a plasma generated remotely from a workpiece, such as in a plasma chamber separated from a workpiece by a separation grid. A “direct plasma” refers to a plasma that is directly exposed to a workpiece, such as a plasma generated in a processing chamber having a pedestal operable to support the workpiece. As used herein, a “peripheral portion” of a workpiece includes the portion of the workpiece within 10 mm of a perimeter edge of the workpiece.

As used herein, use of the term “about” in conjunction with a stated numerical value can include a range of values within 10% of the stated numerical value.

Conventional plasma processing apparatuses may include a processing chamber for treating one or more workpieces with plasma. Such chambers generally include a plasma generation source (e.g., an induction coil) disposed on or around at least a portion of the chamber. Often times, the walls of the processing chamber can be formed from a dielectric material (e.g., ceramic). During processing, material residue and/or material deformations can form around the periphery of the semiconductor wafer. Accordingly, there is a need to selectively remove materials from the peripheral portion of the wafer without exposing the center of the workpiece to additional processing conditions (e.g., plasma). Certain plasma chambers are capable of inducing plasma remotely or within the chamber utilizing a variety of coils that are typically disposed on or around areas of the chamber itself. However, generation of plasma in such a manner exposes the entire workpiece to the plasma.

According to examples of the present disclosure, a plasma processing apparatus is disclosed that includes a processing chamber, a workpiece support disposed in the processing chamber configured to support a workpiece during processing and a hollow cathode disposed in the processing chamber. The hollow cathode is configured to produce a plasma in the processing chamber. The hollow cathode is disposed adjacent to a perimeter of the workpiece support and the workpiece. A gas distribution system for supplying process gas to the processing chamber is also provided. The hollow cathode is configured to etch a peripheral portion of the workpiece during processing.

The plasma processing apparatus according to example embodiments of the present disclosure can provide numerous benefits and technical effects. For instance, plasma processing apparatus provides an efficient way to ignite and generate plasma, reducing overall operational costs. Further, the plasma processing apparatus provides a mechanism to expose only the peripheral portion of the workpiece to dense plasma species to etch only the peripheral portion of the workpiece.

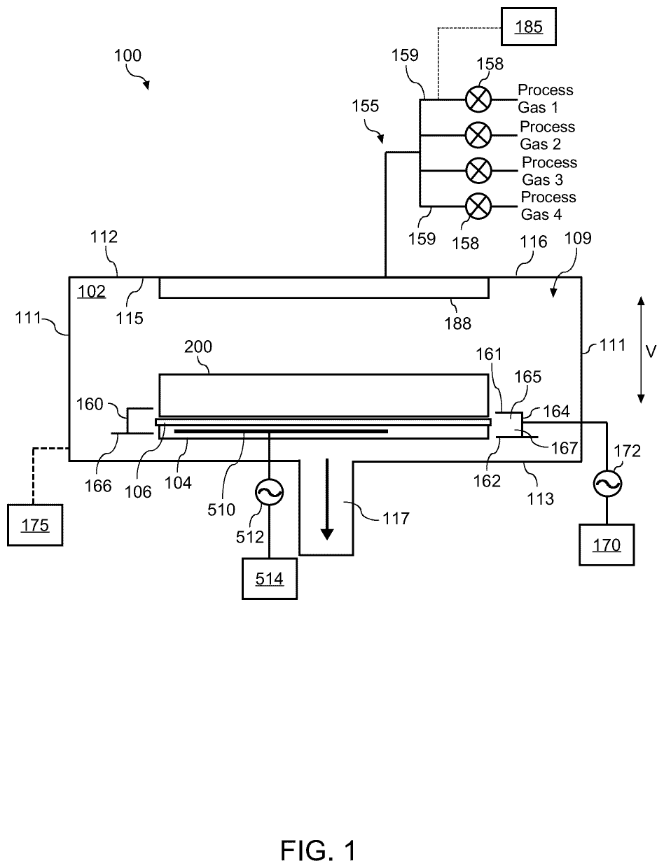

FIG. 1 depicts a plasma processing apparatus 100 according to an example embodiment of the present disclosure. The plasma processing apparatus 100 includes a processing chamber 109 defining an interior space 102. A workpiece support 104 (e.g., pedestal) is used to support a workpiece 106, such as a semiconductor wafer, within the interior space 102. Workpiece support 104 can include one or more support pins, such as at least three support pins, extending from workpiece support 104. (Not shown). In some embodiments, workpiece support 104 can be spaced from the top of the processing chamber 109. The processing chamber 109 includes one or more sidewalls 111, a top 112, and a bottom 113. The top 112 and/or bottom 113 can form a flat surface or can be curved or slightly domed. The top 112 has a first surface 115 facing the interior space 102 of the processing chamber 109 and a second surface 116 opposite from the first surface 115 that faces externally. The sidewalls 111, top 112, and/or bottom 113 of the processing chamber 109 can be formed from a dielectric material.

An exhaust 117 can be located about the bottom 113 of the processing chamber 109 and can be connected to a pump in order to maintain a desired vacuum environment or other desired pressure condition in the processing chamber 109. In some embodiments, the exhaust is located in a central location under the workpiece 106 and workpiece support 104. One or more vacuum pumps can be configured to maintain a vacuum pressure in the processing chamber 109. Further, process gas flow in an out of the processing chamber 109 can be adjusted to achieve the desired vacuum pressure in the processing chamber 109. In embodiments, the vacuum pressure pressures is from about 0.05 Torr to about 10 Torr, such as from about 0.5 Torr to about 9 Torr, such as from about 1 Torr to about 8 Torr, such as from about 2 Torr to about 6 Torr. In some embodiments, the vacuum pressure is from about 0.05 Torr to about 1 Torr, from 0.3 Torr to about 0.8 Torr, from about 0.5 Torr to about 0.7 Torr. The exhaust 117 can also be utilized to evacuate process gas from the processing chamber 109. The vacuum pressure can be selected based on factors such as the desired process (e.g., etch or material deposition) and the workpiece materials.

As shown in FIG. 1, according to example aspects of the present disclosure, the apparatus 100 can include a gas delivery system 155 configured to deliver process gas to the processing chamber 109, for instance, via a gas distribution channel or other distribution system (e.g., showerhead). The gas delivery system 155 can include a plurality of feed gas lines 159. The feed gas lines 159 can be controlled using valves 158 and/or gas flow controllers 185 to deliver a desired amount of gases into the processing chamber 109 as process gas. The gas delivery system 155 can be used for the delivery of any suitable process gas. As used herein “process gas” refers to any suitable gas and includes vapors. Example process gases include oxygen-containing gases (e.g., O₂, O₃, N₂O, H₂O), hydrogen-containing gases (e.g., H₂, D₂), nitrogen-containing gases (e.g., N₂, NH₃, N₂O), fluorine-containing gases (e.g., CF₄, C₂F₄, CHF₃, CH₂F₂, CH₃F, SF₆, NF₃), hydrocarbon-containing gases (e.g., CH₄), or combinations thereof. Other feed gas lines containing other gases can be added as needed. In some embodiments, the process gas can be mixed with an inert gas that can be called a “carrier” gas, such as He, Ar, Ne, Xe, or N₂. A control valve 158 can be used to control a flow rate of each feed gas line to flow a process gas into the processing chamber 109. In embodiments, the gas delivery system 155 can be controlled with a gas flow controller 185.

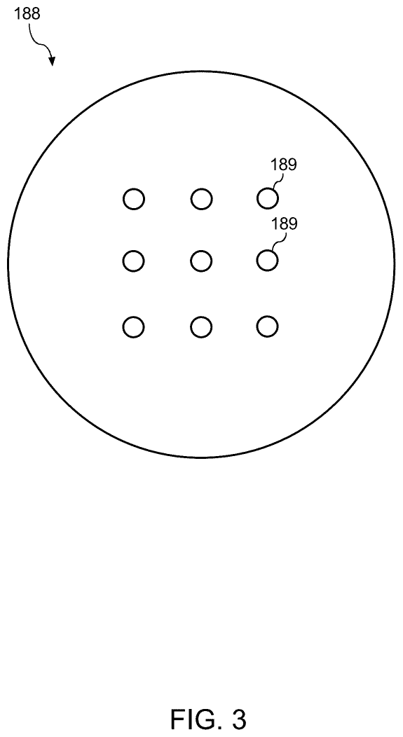

The gas delivery system 155 can be configured to deliver process gas at a high velocity to the processing chamber 109. For instance, the gas delivery system 155 can include a showerhead 188 as illustrated in FIG. 3. As shown, the showerhead 188 can include one or more (e.g., a plurality) of apertures 189 disposed therein. Process gas can be supplied to the showerhead 188 and exit the showerhead 188 into the processing chamber 109 via the apertures 189. To achieve a high velocity flow of process gas into the processing chamber 109, the apertures 189 each can have a diameter ranging from about 0.3 mm to about 1.5 mm, such as about 0.7 mm. In such embodiments having apertures 189 with such small diameters can provide a supersonic spray of process gas into the processing chamber 109, such as by a process called choked flow. In such embodiments, diffusion of process gas in the upper portions of the processing chamber 109 is limited. Indeed, having a high velocity process gas flow also reduces collision of gas molecules, further limiting diffusion of the process gas within the processing chamber 109. As such, process gas can be provided to the workpiece 106 surface maintained at a higher velocity. When the process gas contacts the top surface of the workpiece 106, it can then flow away from the center of the workpiece 106 and to the perimeter of the workpiece 106. Accordingly, the showerhead 188 as described can be useful for maintaining proper gas flow to the hollow cathode 160 to generate a dense plasma as will be further described hereinbelow.

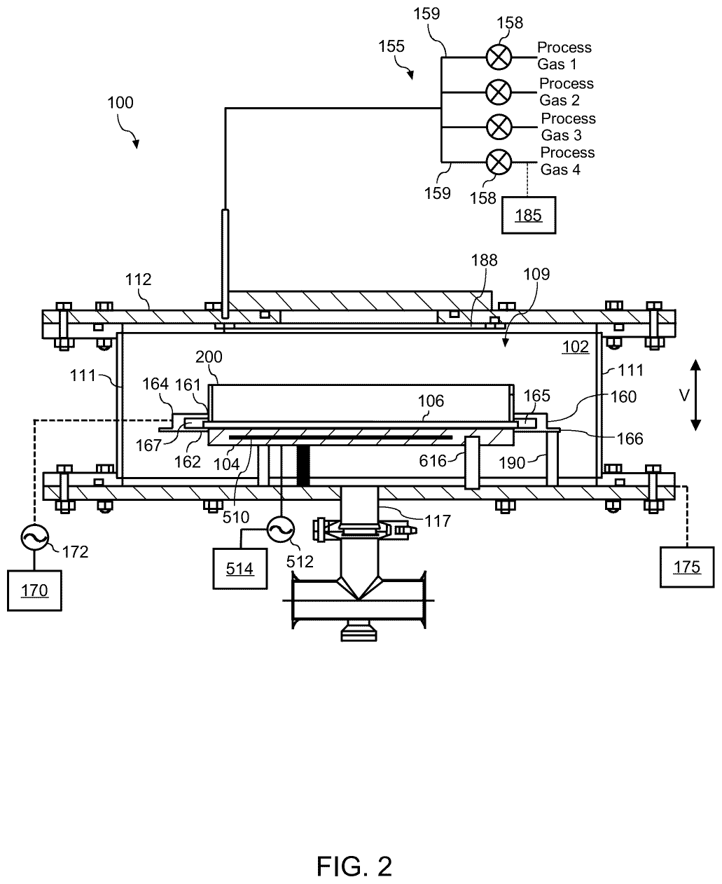

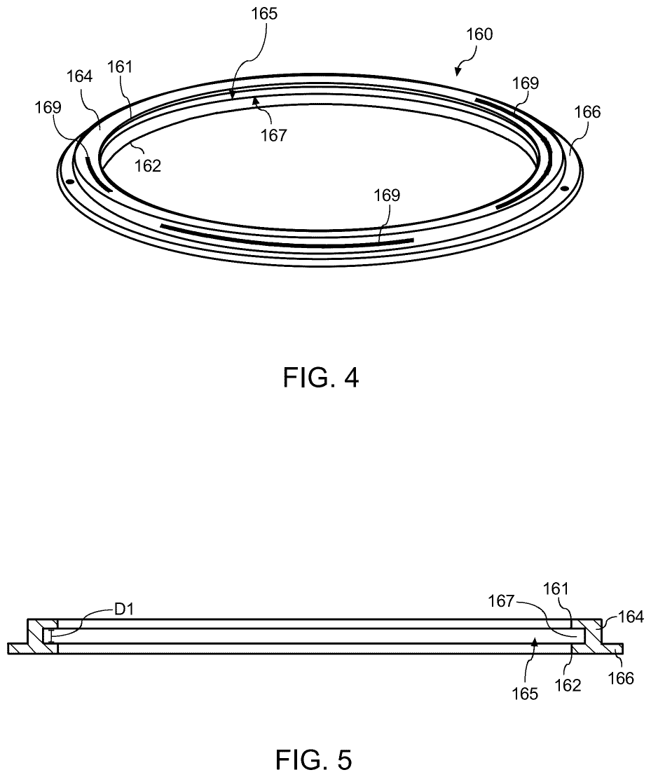

As shown in FIGS. 1-2 the apparatus 100 further includes a hollow cathode 160 disposed within the processing chamber 109. The hollow cathode 160 can be annular in nature and is disposed around the perimeter of the workpiece support 104 and the workpiece 106. The distance between the perimeter edge of the workpiece 106 and the hollow cathode 160 may be in a range from about 1 mm to about 10 mm, such as from about 2 mm to about 9 mm, such as from about 3 mm to about 8 mm, such as from about 4 mm to about 7 mm, such as from about 5 mm to about 6 mm. In certain embodiments, the distance between the perimeter edge of the workpiece 106 and the hollow cathode 160 is from about 1 mm to about 5 mm. For instance, in certain embodiments, the distance between the perimeter edge of the workpiece 106 and the hollow cathode 160 is more than 5 mm so as not to negatively affect the stability of the plasma generated in the hollow cathode 160. The hollow cathode can be formed from metal materials, such as aluminum. In embodiments, the hollow cathode 160 is a C-shaped hollow cathode. As shown in FIGS. 4-5, the hollow cathode 160 can have a first end 161 and a second end 162 connected via a C-shaped member 164. The C-shaped member can be a solid material having no gaps or apertures therein. As shown in FIG. 5, an annular channel 165 is formed within the hollow cathode 160. During operation of the hollow cathode 160, the plasma generation zone 167 is formed within the annular channel 165 of the hollow cathode 160. For instance, the hollow cathode 160 can be electrically coupled to a generator 170, that when supplied with RF power, induces a plasma in the process gas in the plasma generation zone 167 of the plasma processing apparatus 100. For instance, as depicted in FIGS. 1-2, an RF generator 170 can be configured to provide electromagnetic energy through a matching network 172 to the hollow cathode 160. For instance, when supplied with RF power, the hollow cathode 160 emits electrons sufficient to form a plasma from the process gas within the plasma generation zone 167.

Given the configuration of the hollow cathode 160, electrically charged plasma species (e.g., electrons and ions) can become trapped within the plasma generation zone 167 and can resonate within the zone 167 creating a high density plasma. By high density plasma, is meant a plasma having 1-3 orders of magnitude higher of electron density as compared to a plasma generated by a capacitively coupled plasma source. For example, the hollow cathode 160 can provide a plasma having an electron density of about 10¹⁰ cm³ to about 10¹⁵ cm³, such as about 10¹³ cm³. Within the hollow cathode 160, positive ions and high-energy secondary electrons trapped between the walls of the hollow cathode 160 make many collisions with the process gas, thus ionizing the process gas and generating more secondary electrons. Radicals created by collisions with the electrons and ions can escape, making the hollow cathode 160 an efficient producer of neutral radicals. Given the configuration of the hollow cathode 160 as described, high-density plasma can be generated due to the greatly enhanced probability of electron bombardment within the plasma generation zone 167 of the hollow cathode 160.

Further, as shown in FIG. 5, there is a distance D1 located between the first end 161 and the second end 162 of the hollow cathode 160. This distance D1 is generally in the vertical plane and can be modified in order to tune or affect the plasma in the hollow cathode 160. For instance, D1 can be larger or increased when lower pressure plasma processing is desirable. Further, D1 can be smaller or decreased when higher pressure plasma processing is desirable. In embodiments, D1 ranges from about 4 mm to about 15 mm, such as from about 5 mm to about 10 mm, such as from about 6 mm to about 9 mm. In certain embodiments, the distance D1 can be tuned depending on the specific process gas and/or process pressure. For instance, in embodiments where a nitrogen-containing gas is used and the pressure is about 0.7 Torr, the distance D1 can be between about 6 mm to about 10 mm, such as about 9 mm. In other embodiments, where the process gas contains a mixture of a fluorine-containing gas (e.g., CF₄), an oxygen-containing gas (e.g., O₂) and a carrier gas (e.g., Ar), and the pressure is about 0.3 Torr, the distance D1 can be between about 6 mm and to about 10 mm, such as about 9 mm. Still in other embodiments, a distance gradient can exist between the first end 161 and the second end 162 of the hollow cathode 160. (Not shown). For instance, as the first end 161 and second end 162 meet the C-shaped member 164, the distance from the first end 161 or second end 162 to the C-shaped member 164 ca increase, thus creating a smaller opening for the hollow cathode 160 that has an increasing volume towards the inner wall of the C-shaped member 164.

The hollow cathode 160 can be annular in nature (e.g., circular, ovular, etc.) As depicted in FIGS. 4-5, the hollow cathode 160 further includes an annular flange 166 extending outward from the bottom surface of the hollow cathode 160. The annular flange 166 can be coupled to one or more pins 190 for securing the hollow cathode in position in the processing chamber 109. (See FIG. 2). While only pin 190 is illustrated, one or more, such as a plurality of pins 190, can be utilized in accordance with the present disclosure. The pins 190 can be formed from any suitable materials, however, in embodiments, the pins 190 are formed from non-conductive materials, such as ceramic materials. The pins 190 include a first end coupled to the annular flange 166 and a second end coupled to the bottom 113 of the processing chamber 109.

The hollow cathode 160 can be fluid cooled. As depicted in FIG. 4, one or more conduits 169 can be disposed on the hollow cathode 160, for instance, on external surfaces of the hollow cathode 160. Fluid can be flowed through the conduits 169 to cool the hollow cathode 160 either before, during, or after operation of the hollow cathode 160. Suitable fluids can include liquids or gases, including, but not limited to coolant fluids, water, and combinations thereof. Cooling of the hollow cathode 160 can facilitate operation of the hollow cathode 160 at higher powers to generate plasma at high density without the risk of overheating and with a reduced risk of sputtering of the cathode material.

A shield 200 is disposed within the processing chamber 109. The shield 200 can be disposed within the processing chamber 109 at a location above the workpiece 106. For instance, the shield 200 can be disposed in an upper portion of the processing chamber 109. The shield 200 can be formed from any suitable material including metal, quartz, ceramic, or combinations thereof. In embodiments, the shield 200 is formed from a conductive material. In embodiments, the shield is grounded. For instance, suitable grounding components can be placed through the top 112 or the bottom 113 of the processing chamber 109 and electrically coupled to the shield 200 to ground the shield 200. For instance, without this grounding the shield 200 can be electrically coupled to an RF source transmitting from the hollow cathode and RF power can be supplied to the shield 200 creating a plasma inside the shield area. In embodiments, grounding the shield 200 can further help prevent plasma species from going beyond the shield and etching other areas of the workpiece 106, such as the center of the workpiece 106. The shield 200 can also be electrically coupled to the workpiece 106. For instance, a material connection can be utilized to electrically couple the workpiece support 104 through the workpiece 106 to the shield 200. For instance, the shield 200 can include one or more conductive material pieces configured to contact the workpiece 106 when the shield 200 is placed in a processing position. For instance, additional material pieces formed from the same or similar material as the workpiece 106 can be utilized. Such a coupling establishes a capacitive connection between the workpiece support 104, the workpiece 106 and the shield 200 effectively shorting or grounding any RF energy reaching the shield. However, in other embodiments, a capacitive connection between the shield 200 and the workpiece support 104 can act as a low pass electrical filter effectively grounding any RF energy while stopping any DC bias applied to the workpiece support 104. (Not shown). In such an embodiment, RF power can be transmitted to the shield 200 via any suitable source but the shield 200 will be effectively grounded at that frequency.

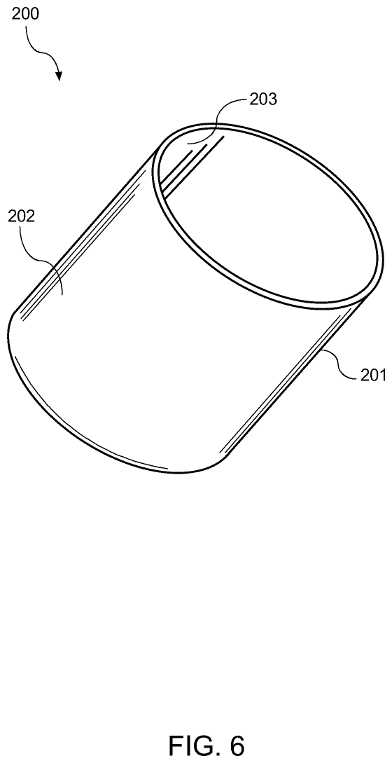

Referring to FIG. 6, the shield 200 can be cylindrical and includes a sidewall 201 having an outer surface 202 and an inner surface 203. The shield 200 is generally open along the top and bottom. When utilized in a processing position within the processing chamber 109, the shield 200 is configured to block one or more plasma species. For instance, as plasma species filter out of the plasma generation zone 167, they contact the workpiece 106. The shield 200 is configured to mechanically block one or more plasma species. For instance, the outer surface 202 of the shield can prevent plasma species from accessing the center of the workpiece 106 or other areas of the workpiece 106. Thus, utilization of the shield 200 can enhance exposure of the perimeter of the workpiece 106 to the plasma species.

The shield 200 and gas distribution system 155 (e.g., the shower head 188) can be disposed such that the apertures 189 of the showerhead 188 are disposed within the inner surface 203 of the shield 200. In such an embodiment, process gas flow remains largely internal within the shield 200 and with a large part of the flow exiting to the processing chamber 109 at the distance located between the bottom of the shield 200 and the top surface of the workpiece 106.

The gas delivery system 155 can be configured to deliver process gas at a high velocity to the processing chamber 109. For instance, the gas delivery system 155 can include a showerhead 188 as illustrated in FIG. 3. As shown, the showerhead 188 can include one or more (e.g., a plurality) of apertures 189 disposed therein. Process gas can be supplied to the showerhead 188 and exit the showerhead 188 into the processing chamber 109 via the apertures 189.

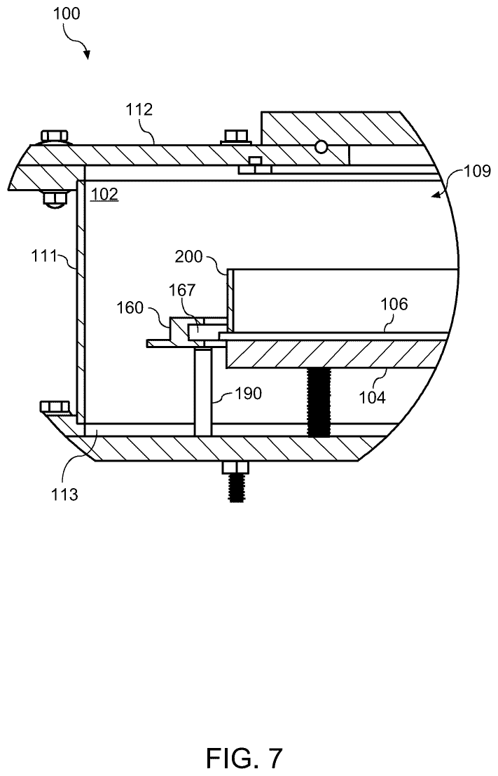

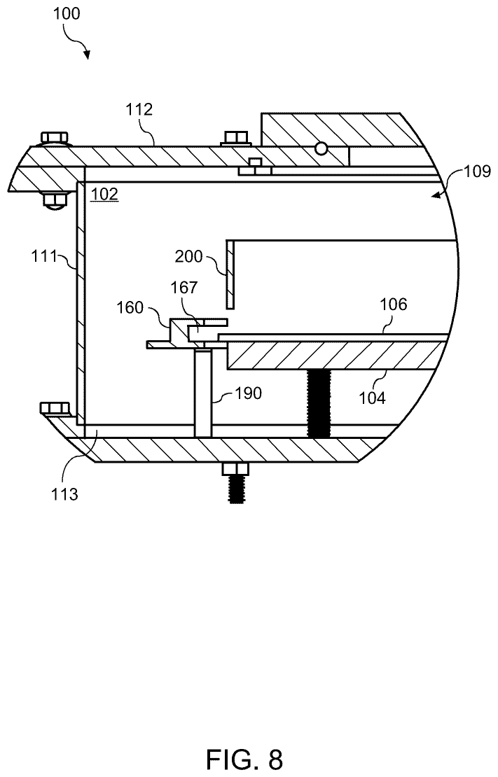

FIGS. 7-8 depict the shield 200 at different vertical positions within the processing chamber 109. During workpiece 106 processing, the shield 200 can be disposed a processing distance from the workpiece 106. The processing distance refers to the distance between the top surface of the workpiece 106 and the bottom of the shield 200. For instance, the processing distance can be about 0.01 mm to about 5 mm, such as from about 0.05 mm to about 4.5 mm, such as from about 0.5 mm to about 4 mm, such as from about 1 mm to about 3 mm. Any suitable mechanism can be disposed within or external to the processing chamber 109 to facilitate vertical movement of the shield 200. For instance, lifts, bellows, and motors can be coupled to the shield 200 and can be configured to move the shield 200 within the plasma chamber 109. As shown in FIG. 7, the shield 200 is placed in a processing distance for workpiece 106 processing. As shown, during processing the shield 200 can be in contact with the workpiece 106 In other embodiments, however, during processing the shield 200 is not in direct contact with either the workpiece 106 or the workpiece support 104. As depicted in FIG. 8, the shield 200 can be placed in a vertical position that is further away from the workpiece 106 and the workpiece support 104. For instance, to facilitate removal of the workpiece 106 from the apparatus 100, the shield 200 can be at least 20 mm away from the workpiece 106 and/or the workpiece support 104. Further, in embodiments the top of the shield 200 is flush with the first surface 115 of the top 112. In such an embodiment, process gas flows vertically down through the shield 200 and exits between the top surface of the workpiece 106 and the bottom of the shield 200. In such embodiments, gas flow velocity can be adjusted to adjust species formation in the plasma or can be adjusted to prevent species from accessing areas of the workpiece 106 located within the shield 200.

Referring back to FIGS. 1-2, the workpiece support 104 can include a bias source having a bias electrode 510 in the workpiece support 104. The bias electrode 510 can be coupled to an RF power generator 514 via a suitable matching network 512. When RF power is applied to the bias electrode 510, species generated in the plasma are attracted to the perimeter of the workpiece 106 and away from the plasma generation zone 167 in the hollow cathode 160. For instance, when negative voltage (e.g., DC bias) is applied to the bias electrode 510, ions from the plasma in the plasma generation zone 167 are attracted to the perimeter of the workpiece 106. Thus, ion acceleration can be achieved via the bias source in the workpiece support 104.

The workpiece support 104 can be movable in a vertical direction V, as shown in FIGS. 1-2. For instance, the workpiece support 104 can include a vertical lift 616 that can be configured to adjust a distance between the workpiece support 104 and the top 112 of the processing chamber 109 and/or the shield 200. As one example, the workpiece support 104 can be located in a first vertical position for processing and can be in a second vertical position to facilitate removal of the workpiece 106. The first vertical position can be closer to the top 112 of the processing chamber 109 or shield 200 relative to the second vertical position.

A controller 175 can be coupled to various components of the plasma processing apparatus 100 to operate the components in a desired manner. For example, the shield 200 can be moved to different vertical positions within the processing chamber 109 via the controller 175. For instance, a processing position and non-processing position can be determined and provided to the controller 175. The controller 175 can include one or more processors and one or more memory devices. The memory device can store and implement computer readable instructions that when executed by the one or more processors cause the one or more processors to perform operations, including implementing any of the control functionality of the present disclosure. Accordingly, when the desired shield position is provided to the controller 175, the controller 175 can operate the mechanical elements in order to move the shield to the desired location within the processing chamber 109. Further, a desired vacuum pressure for the processing chamber 109 can be determined and provided to the controller 175. The controller 175 can then operate the vacuum pump or other exhausts to maintain the desired vacuum pressure for the processing chamber 109.

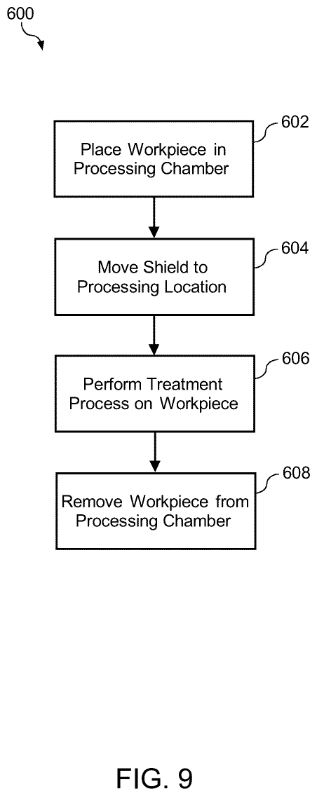

FIG. 9 depicts a flow diagram of one example method (600) according to example aspects of the present disclosure. The method (600) will be discussed with reference to the plasma processing apparatus 100 of FIGS. 1-2 by way of example. The method (600) can be implemented in any suitable plasma processing apparatus. FIG. 9 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various steps (not illustrated) can be performed without deviating from the scope of the present disclosure.

At (602), the method can include placing a workpiece 106 in the processing chamber 109 of a plasma processing apparatus 100. For instance, the workpiece 106 can be placed on a workpiece support 104 disposed in the processing chamber 109.

At (604), the method can include moving the shield 200 to a processing location within the processing chamber 109. The shield 200 can be moved to a vertical position that is a desired processing distance from the workpiece 104. For instance, the processing distance between the shield 200 and the workpiece 106 can be from about 0.01 mm to about 1 mm, from about 0.1 mm to about 0.8 mm, such as about 0.3 mm. Any suitable mechanism can be disposed within or external to the processing chamber 109 to facilitate vertical movement of the shield 200. For instance, lifts, bellows, and motors can be coupled to the shield 200 and can be configured to move the shield 200 within the plasma chamber 109. One or more controllers 175 can be configured to operate mechanical elements configured to move the shield 200 vertically within the processing chamber 109.

At (606), the method can include performing a treatment process on the workpiece 106. For example, the treatment process can include a plasma treatment process. In certain embodiments, the treatment process includes a plasma etch treatment process. The plasma etch treatment process can selectively remove one or more material layers from the workpiece 106. Specifically, in embodiments, the plasma treatment process is a plasma etch process configured to remove material layers from a peripheral portion of the workpiece 106. In other embodiments, the treatment process includes a plasma deposition process. For instance, the plasma deposition process can selectively deposit one or more material layer on the workpiece 106. In embodiments, the plasma treatment process is a plasma deposition process configured to deposit material layer on a peripheral portion of the workpiece 106. Other plasma processes can be used to modify the material layers present on the workpiece. For example, plasma-based surface treatment processes can be utilized to modify the surface morphology of the workpiece or to modify the chemical composition of layers on the workpiece. Any other, known suitable plasma-based processing for workpieces can be performed on the workpiece 106.

In embodiments, the treatment process includes using a hollow cathode 160 to generate a plasma within the processing chamber 109. For instance, the hollow cathode 160 is disposed adjacent to a perimeter of the workpiece support 104 and the workpiece 106. The distance between the perimeter edge of the workpiece 106 and the hollow cathode 160 ranges from about 5 mm to about 10 mm, from about 6 mm to about 9 mm, from about 7 mm to about 8 mm. The hollow cathode can be formed from metal materials, such as aluminum.

In embodiments, as shown in FIG. 5, the hollow cathode 160 is a C-shaped hollow cathode. The hollow cathode 160 can have a first end 161 and a second end 162 connected via a C-shaped member 164. The C-shaped member 164 can be a solid material having no gaps or apertures therein. As shown, an annular channel 165 is formed within the hollow cathode 160. During operation of the hollow cathode 160, the plasma generation zone 167 is formed within the annular channel 165 of the hollow cathode 160. For instance, the hollow cathode 160 can be electrically coupled to a generator 170, that when supplied with RF power, induces a plasma in the process gas in the plasma generation zone 167 of the plasma processing apparatus 100. For instance, an RF generator 170 can be configured to provide electromagnetic energy through a matching network 172 to the hollow cathode 160.

Given the configuration of the hollow cathode 160, plasma species (e.g., electrons and ions) can become trapped within the plasma generation zone 167 and can resonate within the zone 167 creating a high density plasma. By high density plasma, is meant a plasma having 1-3 orders of magnitude higher of electron density as compared to a plasma generated by a capacitively coupled plasma source. For example, the hollow cathode 160 can provide a plasma having an electron density of about 10¹⁰ cm3 to about 10¹⁵ cm3, such as about 10¹³ cm3. Within the hollow cathode 160, positive ions and high-energy secondary electrons trapped between the walls of the hollow cathode 160 make many collisions with the process gas, thus ionizing the process gas and generating more secondary electrons. Radicals created by collision with the electrons and ions can escape, making the hollow cathode 160 an efficient producer of neutral radicals. Given the configuration of the hollow cathode 160 as described, high-density plasma can be generated due to the greatly enhanced probability of electron bombardment within the plasma generation zone 167 of the hollow cathode 160. Thus, during the plasma treatment process, the hollow cathode 160 can be utilized to expose the perimeter of the workpiece 106 to plasma species.

Further, during the plasma treatment process, a shield 200 can be utilized to further direct plasma species to the perimeter of the workpiece 106. For instance, the shield 200 is configured to mechanically block one or more plasma species. For instance, the outer surface 202 of the shield can prevent plasma species from accessing the center of the workpiece 106 or other areas of the workpiece 106. Thus, utilization of the shield 200 can enhance exposure of the perimeter of the workpiece 106 to the plasma species. Accordingly, the plasma treatment process can include utilizing a shield to prevent one or more plasma species from contacting a center portion of the workpiece 106. Further, process gas flow through the shield 200 can be utilized to block plasma species from accessing the center of the workpiece 106. For instance, as process gas flows through the shield 200 and exits between the bottom of the shield and the top of the workpiece, increasing the velocity of the process gas flow can further prevent plasma species from blocking the center of the workpiece 106.

The workpiece support 104 can include a bias source having a bias electrode 510 in the workpiece support 104. The bias electrode 510 can be coupled to an RF power generator 514 via a suitable matching network 512. When RF power is applied to the bias electrode 510, species generated in the plasma are attracted to the perimeter of the workpiece 106 and away from the plasma generation zone 167 in the hollow cathode 160. For instance, when voltage is applied to the bias electrode, ions from the plasma in the plasma generation zone 167 are attracted to the perimeter of the workpiece 106. Thus, ion acceleration can be achieved via the bias source in the workpiece support 104. Accordingly, the plasma treatment process can include accelerating one or more species from the plasma towards a perimeter of the workpiece utilizing a bias source disposed in the workpiece support 104.

At (608) the method can include removing the workpiece from the processing chamber 109. For instance, the workpiece 106 can be removed from workpiece support 104 in the processing chamber 109. To facilitate removal of the workpiece, the workpiece support 104 can be moved in a downward vertical direction away from the top 112 of the processing chamber 109 to facilitate removal of the workpiece 106 from the workpiece support. The plasma processing apparatus can then be conditioned for future processing of additional workpieces.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A plasma processing apparatus, comprising:
a processing chamber;
a workpiece support disposed in the processing chamber configured to support a workpiece during processing;
a hollow cathode disposed in the processing chamber configured to produce a plasma in the processing chamber, wherein the hollow cathode is disposed adjacent to a perimeter of the workpiece support and the workpiece; and
a gas distribution system configured to provide process gas to the processing chamber.

2. The plasma processing apparatus of claim 1, wherein the plasma is configured to etch a peripheral portion of the workpiece.

3. The plasma processing apparatus of claim 1, wherein the hollow cathode comprises a plasma generation zone disposed within a portion of the hollow cathode between the workpiece and the hollow cathode.

4. The plasma processing apparatus of claim 1, comprising a shield disposed within the processing chamber at a location above the workpiece.

5. The plasma processing apparatus of claim 4, wherein the shield can be moved to one or more vertical positions within the processing chamber.

6. The plasma processing apparatus of claim 4, wherein the shield is grounded.

7. The plasma processing apparatus of claim 4, wherein the shield is electrically coupled to the workpiece support.

8. The plasma processing apparatus of claim 4, wherein the shield is configured to block one or more plasma species.

9. The plasma processing apparatus of claim 4, wherein, during processing, the shield is disposed a processing distance from the workpiece, wherein the processing distance is in a range of about 0.01 mm to about 10 mm.

10. The plasma processing apparatus of claim 4, wherein the shield is cylindrical and includes a sidewall having an outer surface and an inner surface.

11. The plasma processing apparatus of claim 4, comprising one or more bellows configured to move the shield to one or more vertical positions within the processing chamber.

12. The plasma processing apparatus of claim 1, wherein the gas distribution system comprises a showerhead having one or more apertures disposed therein.

13. The plasma processing apparatus of claim 12, comprising a shield disposed within the processing chamber at a location above the workpiece, the shield having an inner surface and an outer surface, wherein the one or more apertures are disposed internally from the inner surface of the shield.

14. The plasma processing apparatus of claim 1, wherein the hollow cathode is secured via one or more pins extending from a bottom of the processing chamber.

15. The plasma processing apparatus of claim 1, wherein the workpiece support comprises a bias electrode configured to apply a DC bias or RF power to the workpiece support.

16. The plasma processing apparatus of claim 1, wherein the hollow cathode is fluid cooled.

17. The plasma processing apparatus of claim 16, comprising one or more conduits disposed on the hollow cathode, configured to provide fluid to the hollow cathode.

18. The plasma processing apparatus of claim 1, wherein the processing chamber is configured to maintain a vacuum pressure of from about 0.05 to about 10 Torr.

19. The plasma processing apparatus of claim 1, wherein a distance between a perimeter edge of the workpiece and the cathode is in a range of about 5 mm to about 10 mm.
